(19) United States
(12) Patent Application Publication
(10) Pub. No.: US 2025/0004714 A1
(43) Pub. Date: Jan. 2, 2025

(54) BLOCK FLOATING POINT CONVERSION

(71) Applicant: Telefonaktiebolaget LM Ericsson (publ), Stockholm (SE)

(72) Inventor: Ricardo PAREDES CABRERA, Ottawa (CA)

(21) Appl. No.: 18/710,430

(22) PCT Filed: Dec. 13, 2022
(86) PCT No.: PCT/IB2022/062154

§ 371 Date: May 15, 2024

Related U.S. Application Data
(60) Provisional application No. 63/289,289, filed on Dec. 14, 2021.

(51) Int. Cl. G06F 7/483

(52) U.S. Cl. CPC G06F 7/483

(57) ABSTRACT

A method, system and apparatus are disclosed. A computing device is described. The computing device comprises processing circuitry configured to convert a first data block comprising a first plurality of data samples in a first format to a second data block comprising a second plurality of data samples in a second format. The conversion is performed without at least one of decompressing and compressing the first plurality of data samples. Further, the conversion is one of output size dependent and output size independent. In addition, the processing circuitry is configured to perform at least one action based on the conversion of the first data block.

### TECHNICAL FIELD

The present disclosure relates to data conversion, and in particular, to block floating point (BFP) conversion without decompressing and compressing the data after, for example, the initial block floating point (BFP) compression may be used, for example, in wireless communication networks.

### BACKGROUND

Data compression using block floating point (BFP) is commonly used in wireless networks and other areas where a large number of data samples is processed. Some servers and network nodes already have hardware support for one or more BFP compression (and/or decompression) algorithms. For example, open random access network (ORAN) standards have defined user plane packets to encode in-phase/quadrature (IQ) samples in BFP format. One purpose of the BFP compression is to reduce data samples from (e.g., IQ data, video, etc.) where there is a large amount of data to process and transmit/receive. Compressed data is typically decompressed before being used. However, such a reduction of data samples (associated with compression and decompression) may result in a loss of data and/or data accuracy.

In sum, compression and decompression processes of existing systems are complex and typically result in data loss or data inaccuracies.

### SUMMARY

Some embodiments advantageously provide methods, systems, and apparatuses for block floating point (BFP) conversion without decompressing and compressing again the data.

In some embodiments, it is possible to reduce cost and time by using the existing BFP algorithm as the starting point for a new algorithm (e.g., in cases when a BFP compression algorithm is required). The outputs of a BFP algorithm can be used as inputs to the functions defined herein to simplify the implementation.

In one or more embodiments, a low complexity and efficient algorithm to convert from one BFP format to another without decompressing the data samples is provided. The algorithm also allows to combining multiple blocks with different exponents into a block with one exponent.

According to one aspect, a computing device is described. The computing device comprises processing circuitry configured to convert a first data block comprising a first plurality of data samples in a first format to a second data block comprising a second plurality of data samples in a second format. The conversion is performed without at least one of decompressing and compressing the first plurality of data samples. Further, the conversion is one of output size dependent and output size independent. In addition, the processing circuitry is configured to perform at least one action based on the conversion of the first data block.

In some embodiments, the first data block comprises a first least significant bit (LSB), the second data block comprises a second LSB, and the conversion of the first data block includes determining a first bit string based on whether the conversion is one of output size dependent and output size independent, where the first bit string comprises a first bit string LSB; and appending the first bit string to the right of the second LSB of the second data block. The first bit string LSB of the first bit string becomes the only LSB of the appended second data block.

In some other embodiments, the first data block comprises at least a first exponent, and the first bit string comprises at least a second exponent.

In an embodiment, the processing circuitry is further configured to, when the conversion is output size dependent, determine the at least second exponent to be the same as the at least first exponent if a first size of the first plurality of data samples is less than or equal to a second size of the second plurality of data samples; and based at least in part on a minimum exponent value of the at least first exponent if the first size of the first plurality of data samples is greater than the second size of the second plurality of data samples.

In another embodiment, the processing circuitry is further configured to, when the conversion is output size independent, determine the at least second exponent to be the same as the at least first exponent if the first size of the first plurality of data samples is less than or equal to the second size of the second plurality of data samples; and based at least in part on a maximum exponent value of the at least first exponent if the first size of the first plurality of data samples is greater than the second size of the second plurality of data samples.

In some embodiments, the conversion of the first data block further includes appending a plurality of padding bits to the first data block; determining a plurality of right shift bits, the plurality of right shift bits being based on the minimum exponent value when the conversion is output size dependent, the plurality of right shift bits being based on the maximum exponent value when the conversion is output size independent; and shifting the first plurality of data samples to the right by a number of bits equal to the plurality of right shift bits.

In some other embodiments, the conversion of the first data block further includes setting at least one bit of the plurality of right shift bits to zero when a first value associated with the first plurality of data samples is positive; and setting at least one other bit of the plurality of right shift bits to one when a second value associated with the first plurality of data samples is negative.

In an embodiment, the second data block further includes a second most significant bit (MSB), and the conversion of the first data block includes when a third value associated with the first plurality of data samples is a negative value, inserting a second bit string to the right of the second MSB. Each bit of the second bit string is equal to one.

In another embodiment, the first data block is a first block float point (BFP) block, and the second data block is a second BFP block.

In some embodiments, the performing of the at least one action includes at least one of receiving the first data block; transmitting the second data block; extract data from at least from the second plurality of data samples; and perform at least one network function based on the extracted data.

According to another aspect, a method in a computing device is described. The method comprises converting a first data block comprising a first plurality of data samples in a first format to a second data block comprising a second plurality of data samples in a second format. The conversion is performed without at least one of decompressing and compressing the first plurality of data samples. Further, the conversion is one of output size dependent and output size independent. In addition, at least one action is performed based on the conversion of the first data block.

In some embodiments, the first data block comprises a first least significant bit (LSB), the second data block comprises a second LSB, and the conversion of the first data block includes determining a first bit string based on whether the conversion is one of output size dependent and output size independent. The first bit string comprises a first bit string LSB. Further, the first bit string is appended to the right of second LSB of the second data block, where the first bit string LSB of the first bit string becomes the only LSB of the appended second data block.

In some other embodiments, the first data block comprises at least a first exponent, and the first bit string comprises at least a second exponent.

In an embodiment, the method further includes, when the conversion is output size dependent, determining the at least second exponent to be the same as the at least first exponent if a first size of the first plurality of data samples is less than or equal to a second size of the second plurality of data samples; and based at least in part on a minimum exponent value of the at least first exponent if the first size of the first plurality of data samples is greater than the second size of the second plurality of data samples.

In another embodiment, the method further includes, when the conversion is output size independent, determining the at least second exponent to be the same as the at least first exponent if the first size of the first plurality of data samples is less than or equal to the second size of the second plurality of data samples; and based at least in part on a maximum exponent value of the at least first exponent if the first size of the first plurality of data samples is greater than the second size of the second plurality of data samples.

In some embodiments, the conversion of the first data block further includes appending a plurality of padding bits to the first data block; determining a plurality of right shift bits, where the plurality of right shift bits is based on the minimum exponent value when the conversion is output size dependent. The plurality of right shift bits is based on the maximum exponent value when the conversion is output size independent. In addition, the first plurality of data samples is shifted to the right by a number of bits equal to the plurality of right shift bits.

In some other embodiments, the conversion of the first data block further includes setting at least one bit of the plurality of right shift bits to zero when a first value associated with the first plurality of data samples is positive; and setting at least one other bit of the plurality of right shift bits to one when a second value associated with the first plurality of data samples is negative.

In an embodiment, the second data block further includes a second most significant bit (MSB), and the conversion of the first data block includes, when a third value associated with the first plurality of data samples is a negative value, inserting a second bit string to the right of the second MSB. Each bit of the second bit string is equal to one.

In another embodiment, the first data block is a first block float point (BFP) block, and the second data block is a second BFP block.

In some embodiments, the performing of the at least one action includes at least one of receiving the first data block; transmitting the second data block; extracting data from at least from the second plurality of data samples; and performing at least one network function based on the extracted data.

### BRIEF DESCRIPTION OF THE DRAWINGS

A more complete understanding of the present embodiments, and the attendant advantages and features thereof, will be more readily understood by reference to the following detailed description when considered in conjunction with the accompanying drawings wherein:

FIG. 1 is a schematic diagram of an example network architecture illustrating a communication system connected via an intermediate network to a host computer that implement the BFP conversion according to the principles in the present disclosure;

FIG. 2 is a block diagram of a host computer communicating via a network node with a wireless device over an at least partially wireless connection according to some embodiments of the present disclosure;

FIG. 3 is a flowchart illustrating example methods implemented in a communication system including a host computer, a network node and a wireless device for executing a client application at a wireless device according to some embodiments of the present disclosure;

FIG. 4 is a flowchart illustrating example methods implemented in a communication system including a host computer, a network node and a wireless device for receiving user data at a wireless device according to some embodiments of the present disclosure;

FIG. 5 is a flowchart illustrating example methods implemented in a communication system including a host computer, a network node and a wireless device for receiving user data from the wireless device at a host computer according to some embodiments of the present disclosure;

FIG. 6 is a flowchart illustrating example methods implemented in a communication system including a host computer, a network node and a wireless device for receiving user data at a host computer according to some embodiments of the present disclosure;

FIG. 7 is a flowchart of an example process in a network node according to some embodiments of the present disclosure;

FIG. 8 is a flowchart of an example process in a network node according to some embodiments of the present disclosure;

FIG. 9 is another schematic diagram of an example network architecture using uplink IQ antenna data processing and transmission according to some embodiments of the present disclosure;

FIG. 10 is an example conversion of positive values (e.g., output size dependent), according to some embodiments of the present disclosure;

FIG. 11 is an example conversion of negative values in two's complement (e.g., an output size dependent) according to some embodiments of the present disclosure;

FIG. 12 is an example conversion of positive values (e.g., output size independent) according to some embodiments of the present disclosure;

FIG. 13 is an example conversion of negative values in two's complement (output size independent) according to some embodiments of the present disclosure;

FIG. 14 is an example exponent calculation (output size dependent) according to some embodiments of the present disclosure;

FIG. 15 is an example value calculation (output size dependent) according to some embodiments of the present disclosure;

FIG. 16 is an example exponent calculation (output size independent) according to some embodiments of the present disclosure; and

FIG. 17 is an example value calculation (output size independent) according to some embodiments of the present disclosure.

### DETAILED DESCRIPTION

Before describing in detail exemplary embodiments, it is noted that the embodiments reside primarily in combinations of apparatus components and processing steps related to block floating point (BFP) conversion without decompressing and compressing again the data. Accordingly, components have been represented where appropriate by conventional symbols in the drawings, showing only those specific details that are pertinent to understanding the embodiments so as not to obscure the disclosure with details that will be readily apparent to those of ordinary skill in the art having the benefit of the description herein. Like numbers refer to like elements throughout the description.

As used herein, relational terms, such as “first” and “second,” “top” and “bottom,” and the like, may be used solely to distinguish one entity or element from another entity or element without necessarily requiring or implying any physical or logical relationship or order between such entities or elements. The terminology used herein is for the purpose of describing particular embodiments only and is not intended to be limiting of the concepts described herein. As used herein, the singular forms “a”. “an” and “the” are intended to include the plural forms as well, unless the context clearly indicates otherwise. It will be further understood that the terms “comprises,” “comprising.” “includes” and/or “including” when used herein, specify the presence of stated features, integers, steps, operations, elements, and/or components, but do not preclude the presence or addition of one or more other features, integers, steps, operations, elements, components, and/or groups thereof.

In embodiments described herein, the joining term, “in communication with” and the like, may be used to indicate electrical or data communication, which may be accomplished by physical contact, induction, electromagnetic radiation, radio signaling, infrared signaling or optical signaling, for example. One having ordinary skill in the art will appreciate that multiple components may interoperate and modifications and variations are possible of achieving the electrical and data communication.

In some embodiments described herein, the term “coupled,” “connected,” and the like, may be used herein to indicate a connection, although not necessarily directly, and may include wired and/or wireless connections.

The Third Generation Partnership Project (3GPP) has developed and is developing standards for Fourth Generation (4G) (also referred to as Long Term Evolution (LTE)) and Fifth Generation (5G) (also referred to as New Radio (NR)) wireless communication systems and even Sixth Generation (6G) wireless communication systems. Such systems provide, among other features, broadband communication between network nodes, such as base stations, and mobile wireless devices (WD), as well as communication between network nodes and between WDs. Thus, one or more of the embodiments described herein may be applicable to and/or usable on wireless communication networks based on 3GPP standards.

The term “network node” used herein can be any kind of network node comprised in a radio network which may further comprise any of base station (BS), radio base station, base transceiver station (BTS), base station controller (BSC), radio network controller (RNC), g Node B (gNB), evolved Node B (eNB or eNodeB), Node B, multi-standard radio (MSR) radio node such as MSR BS, multi-cell/multicast coordination entity (MCE), integrated access and backhaul (IAB) node, relay node, donor node controlling relay, radio access point (AP), transmission points, transmission nodes, a centralized unit (CU), a distributed/digital unit (DU) such as a virtual DU (vDU), radio unit which may communicate (via a fronthaul connection) with a vDU, Remote Radio Unit (RRU), Remote Radio Head (RRH), a core network node (e.g., mobile management entity (MME), self-organizing network (SON) node, a coordinating node, positioning node, MDT node, etc.), an external node (e.g., 3^{rd} party node, a node external to the current network), nodes in distributed antenna system (DAS), a spectrum access system (SAS) node, an element management system (EMS), etc. The network node may also comprise test equipment. The term “radio node” used herein may be used to also denote a wireless device (WD) such as a wireless device (WD) or a radio network node.

In some embodiments, the non-limiting terms wireless device (WD) or a user equipment (UE) are used interchangeably. The WD herein can be any type of wireless device capable of communicating with a network node or another WD over radio signals, such as wireless device (WD). The WD may also be a radio communication device, target device, device to device (D2D) WD, machine type WD or WD capable of machine to machine communication (M2M), low-cost and/or low-complexity WD, a sensor equipped with WD, Tablet, mobile terminals, smart phone, laptop embedded equipped (LEE), laptop mounted equipment (LME), USB dongles, Customer Premises Equipment (CPE), an Internet of Things (IoT) device, or a Narrowband IoT (NB-IoT) device, etc.

Also, in some embodiments the generic term “radio network node” is used. It can be any kind of a radio network node which may comprise any of base station, radio base station, base transceiver station, base station controller, network controller, RNC, evolved Node B (eNB), Node B, gNB, Multi-cell/multicast Coordination Entity (MCE), IAB node, relay node, access point, radio access point, Remote Radio Unit (RRU) Remote Radio Head (RRH).

Note that although terminology from one particular wireless system, such as, for example, 3GPP LTE and/or New Radio (NR), may be used in this disclosure, this should not be seen as limiting the scope of the disclosure to only the aforementioned system. Other wireless systems, including without limitation Wide Band Code Division Multiple Access (WCDMA), Worldwide Interoperability for Microwave Access (WiMax), Ultra Mobile Broadband (UMB) and Global System for Mobile Communications (GSM), may also benefit from exploiting the ideas covered within this disclosure.

Note further, that functions described herein as being performed by a wireless device or a network node may be distributed over a plurality of wireless devices and/or network nodes. In other words, it is contemplated that the functions of the network node and wireless device described herein are not limited to performance by a single physical device and, in fact, can be distributed among several physical devices.

In one or more embodiments, the term “block” is used and may refer to one or more bits of data, information such as control information and/or signaling, etc. The block may refer to a data block or a control block. In some embodiments, the term “data block” is used and may refer to a block.

In some embodiments the term least significant bit (LSB) is used which may refer to the position in a bit string of a sample representing the bit with the lowest value. In some embodiments, the LSB may be fixed to the right most bit position in each sample. In some other embodiments, a resulting output sample has also the right most bit position as the LSB. The term most significant bit may refer to the position in a bit string of a sample representing the bit with the highest value. In some embodiments, the LSB and MSB are computer architecture dependent, e.g., for example, using big endian versus little endian or host byte order versus network byte order may influence how a value is interpreted from the bit string.

In some embodiments, the terms output size dependent and output size independent are used. In an embodiment, output size dependent may refer to an exponent of a block that depends on the size of the uncompressed sample. In another embodiment, output size independent refers to the exponent of a block that does not depend on the size of the uncompressed sample.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Some embodiments provide BFP conversion without decompressing and compressing again the data. While BFP conversion is discussed below as being performed in a network node, other nodes/devices (e.g., WD, host computer, etc.) in and out of the network may be configured to perform BFP conversion in accordance with the teachings herein.

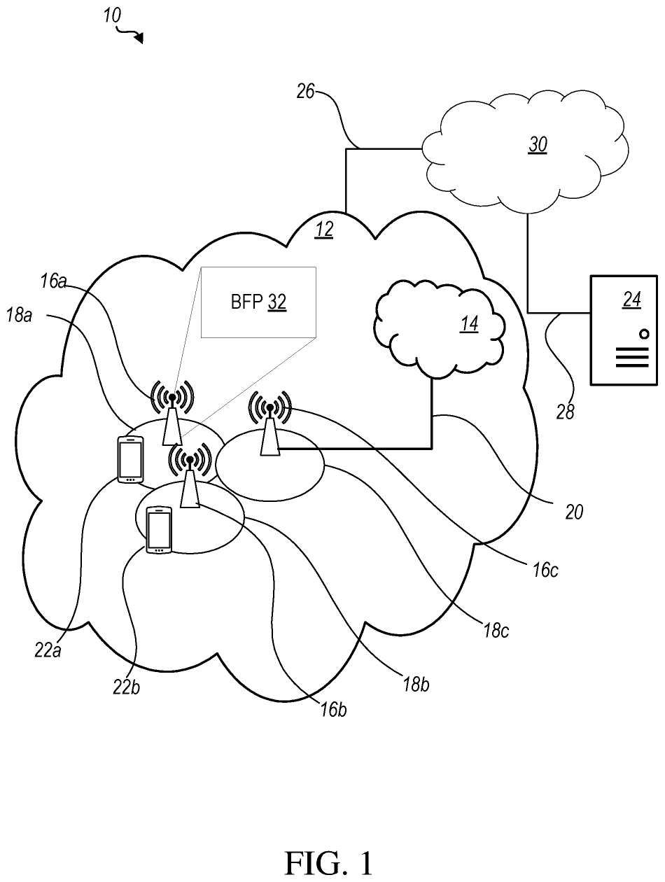

Referring now to the drawing figures, in which like elements are referred to by like reference numerals, there is shown in FIG. 1 a schematic diagram of a communication system 10, according to an embodiment, such as a 3GPP-type cellular network that may support standards such as LTE and/or NR (5G), which comprises an access network 12, such as a radio access network, and a core network 14. The access network 12 comprises a plurality of network nodes 16a, 16b, 16c (referred to collectively as network nodes 16), such as NBs, eNBs, gNBs or other types of wireless access points, each defining a corresponding coverage area 18a, 18b, 18c (referred to collectively as coverage areas 18). Each network node 16a, 16b, 16c is connectable to the core network 14 over a wired or wireless connection 20. A first wireless device (WD) 22a located in coverage area 18a is configured to wirelessly connect to, or be paged by, the corresponding network node 16a. A second WD 22b in coverage area 18b is wirelessly connectable to the corresponding network node 16b. While a plurality of WDs 22a, 22b (collectively referred to as wireless devices 22) are illustrated in this example, the disclosed embodiments are equally applicable to a situation where a sole WD is in the coverage area or where a sole WD is connecting to the corresponding network node 16. Note that although only two WDs 22 and three network nodes 16 are shown for convenience, the communication system may include many more WDs 22 and network nodes 16.

Also, it is contemplated that a WD 22 can be in simultaneous communication and/or configured to separately communicate with more than one network node 16 and more than one type of network node 16. For example, a WD 22 can have dual connectivity with a network node 16 that supports LTE and the same or a different network node 16 that supports NR. As an example, WD 22 can be in communication with an eNB for LTE/E-UTRAN and a gNB for NR/NG-RAN.

That said, it is noted that implementations are not limited to 3GPP implementations and that examples provided herein relating to 3GPP implementations are illustrative in nature to aid understanding as to how the BFP arrangements provided herein could be implemented. Further, although BFP arrangements provided herein may be described with reference to a network node 16, it is contemplated that the BFP arrangements provided herein can be implemented in computing devices other than a network node 16, e.g., a server.

The communication system 10 may itself be connected to a host computer 24, which may be embodied in the hardware and/or software of a standalone server, a cloud-implemented server, a distributed server or as processing resources in a server farm. The host computer 24 may be under the ownership or control of a service provider, or may be operated by the service provider or on behalf of the service provider. The connections 26, 28 between the communication system 10 and the host computer 24 may extend directly from the core network 14 to the host computer 24 or may extend via an optional intermediate network 30. The intermediate network 30 may be one of, or a combination of more than one of, a public, private or hosted network. The intermediate network 30, if any, may be a backbone network or the Internet. In some embodiments, the intermediate network 30 may comprise two or more sub-networks (not shown).

The communication system of FIG. 1 as a whole enables connectivity between one of the connected WDs 22a, 22b and the host computer 24. The connectivity may be described as an over-the-top (OTT) connection. The host computer 24 and the connected WDs 22a, 22b are configured to communicate data and/or signaling via the OTT connection, using the access network 12, the core network 14, any intermediate network 30 and possible further infrastructure (not shown) as intermediaries. The OTT connection may be transparent in the sense that at least some of the participating communication devices through which the OTT connection passes are unaware of routing of uplink and downlink communications. For example, a network node 16 may not or need not be informed about the past routing of an incoming downlink communication with data originating from a host computer 24 to be forwarded (e.g., handed over) to a connected WD 22a. Similarly, the network node 16 need not be aware of the future routing of an outgoing uplink communication originating from the WD 22a towards the host computer 24.

A network node 16 is configured to include a BFP unit 32 which is configured to perform one or more functions as described herein such as with respect to block floating point (BFP) conversion without decompressing and compressing again the data.

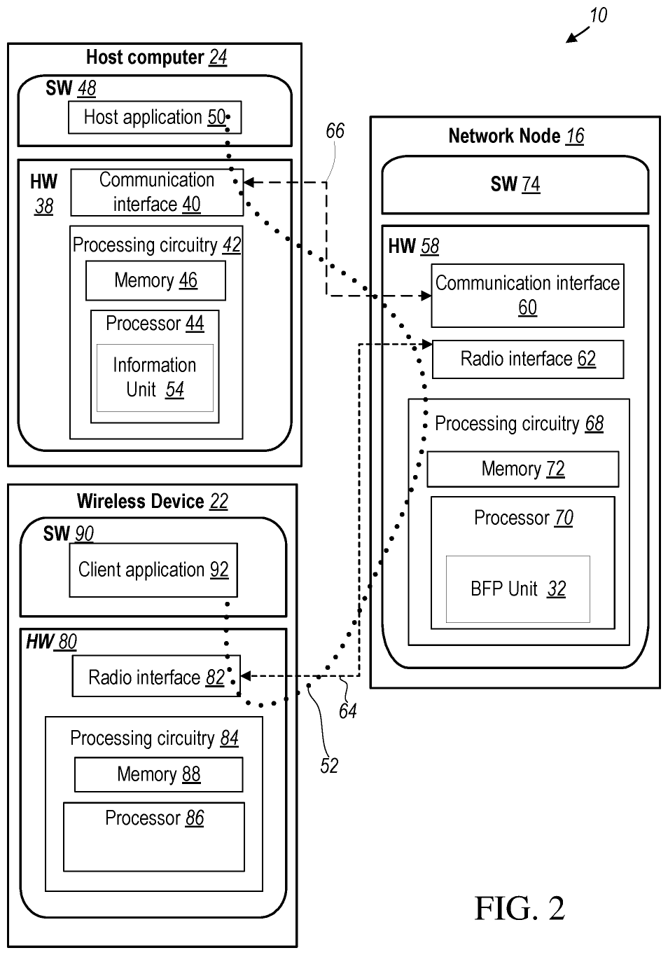

Example implementations, in accordance with an embodiment, of the WD 22, network node 16 and host computer 24 discussed in the preceding paragraphs will now be described with reference to FIG. 2. In a communication system 10, a host computer 24 comprises hardware (HW) 38 including a communication interface 40 configured to set up and maintain a wired or wireless connection with an interface of a different communication device of the communication system 10. The host computer 24 further comprises processing circuitry 42, which may have storage and/or processing capabilities. The processing circuitry 42 may include a processor 44 and memory 46. In particular, in addition to or instead of a processor, such as a central processing unit, and memory, the processing circuitry 42 may comprise integrated circuitry for processing and/or control, e.g., one or more processors and/or processor cores and/or FPGAs (Field Programmable Gate Array) and/or ASICs (Application Specific Integrated Circuitry) adapted to execute instructions. The processor 44 may be configured to access (e.g., write to and/or read from) memory 46, which may comprise any kind of volatile and/or nonvolatile memory, e.g., cache and/or buffer memory and/or RAM (Random Access Memory) and/or ROM (Read-Only Memory) and/or optical memory and/or EPROM (Erasable Programmable Read-Only Memory).

Processing circuitry 42 may be configured to control any of the methods and/or processes described herein and/or to cause such methods, and/or processes to be performed, e.g., by host computer 24. Processor 44 corresponds to one or more processors 44 for performing host computer 24 functions described herein. The host computer 24 includes memory 46 that is configured to store data, programmatic software code and/or other information described herein. In some embodiments, the software 48 and/or the host application 50 may include instructions that, when executed by the processor 44 and/or processing circuitry 42, causes the processor 44 and/or processing circuitry 42 to perform the processes described herein with respect to host computer 24. The instructions may be software associated with the host computer 24.

The software 48 may be executable by the processing circuitry 42. The software 48 includes a host application 50. The host application 50 may be operable to provide a service to a remote user, such as a WD 22 connecting via an OTT connection 52 terminating at the WD 22 and the host computer 24. In providing the service to the remote user, the host application 50 may provide user data which is transmitted using the OTT connection 52. The “user data” may be data and information described herein as implementing the described functionality. In one embodiment, the host computer 24 may be configured for providing control and functionality to a service provider and may be operated by the service provider or on behalf of the service provider. The processing circuitry 42 of the host computer 24 may enable the host computer 24 to observe, monitor, control, transmit to and/or receive from the network node 16 and or the wireless device 22. The processing circuitry 42 of the host computer 24 may include an information unit 54 configured to enable the service provider to communicate, relay, forward, transmit, receive, etc. information related to block floating point (BFP) conversion without decompressing and compressing again the data, and/or to perform the conversion process for another node in system 10.

The communication system 10 further includes a network node 16 provided in a communication system 10 and including hardware 58 enabling it to communicate with the host computer 24 and with the WD 22. The hardware 58 may include a communication interface 60 for setting up and maintaining a wired or wireless connection with an interface of a different communication device of the communication system 10, as well as a radio interface 62 for setting up and maintaining at least a wireless connection 64 with a WD 22 located in a coverage area 18 served by the network node 16. The radio interface 62 may be formed as or may include, for example, one or more RF transmitters, one or more RF receivers, and/or one or more RF transceivers. The communication interface 60 may be configured to facilitate a connection 66 to the host computer 24. The connection 66 may be direct or it may pass through a core network 14 of the communication system 10 and/or through one or more intermediate networks 30 outside the communication system 10.

In the embodiment shown, the hardware 58 of the network node 16 further includes processing circuitry 68. The processing circuitry 68 may include a processor 70 and a memory 72. In particular, in addition to or instead of a processor, such as a central processing unit, and memory, the processing circuitry 68 may comprise integrated circuitry for processing and/or control, e.g., one or more processors and/or processor cores and/or FPGAs (Field Programmable Gate Array) and/or ASICs (Application Specific Integrated Circuitry) adapted to execute instructions. The processor 70 may be configured to access (e.g., write to and/or read from) the memory 72, which may comprise any kind of volatile and/or nonvolatile memory, e.g., cache and/or buffer memory and/or RAM (Random Access Memory) and/or ROM (Read-Only Memory) and/or optical memory and/or EPROM (Erasable Programmable Read-Only Memory).

Thus, the network node 16 further has software 74 stored internally in, for example, memory 72, or stored in external memory (e.g., database, storage array, network storage device, etc.) accessible by the network node 16 via an external connection. The software 74 may be executable by the processing circuitry 68. The processing circuitry 68 may be configured to control any of the methods and/or processes described herein and/or to cause such methods, and/or processes to be performed, e.g., by network node 16. Processor 70 corresponds to one or more processors 70 for performing network node 16 functions described herein. The memory 72 is configured to store data, programmatic software code and/or other information described herein. In some embodiments, the software 74 may include instructions that, when executed by the processor 70 and/or processing circuitry 68, causes the processor 70 and/or processing circuitry 68 to perform the processes described herein with respect to network node 16. For example, processing circuitry 68 of the network node 16 may include BFP unit 32 configured to perform one or more network node 16 functions as described herein such as with respect to block floating point (BFP) conversion without decompressing and compressing again the data.

The communication system 10 further includes the WD 22 already referred to. The WD 22 may have hardware 80 that may include a radio interface 82 configured to set up and maintain a wireless connection 64 with a network node 16 serving a coverage area 18 in which the WD 22 is currently located. The radio interface 82 may be formed as or may include, for example, one or more RF transmitters, one or more RF receivers, and/or one or more RF transceivers.

The hardware 80 of the WD 22 further includes processing circuitry 84. The processing circuitry 84 may include a processor 86 and memory 88. In particular, in addition to or instead of a processor, such as a central processing unit, and memory, the processing circuitry 84 may comprise integrated circuitry for processing and/or control, e.g., one or more processors and/or processor cores and/or FPGAs (Field Programmable Gate Array) and/or ASICs (Application Specific Integrated Circuitry) adapted to execute instructions. The processor 86 may be configured to access (e.g., write to and/or read from) memory 88, which may comprise any kind of volatile and/or nonvolatile memory, e.g., cache and/or buffer memory and/or RAM (Random Access Memory) and/or ROM (Read-Only Memory) and/or optical memory and/or EPROM (Erasable Programmable Read-Only Memory).

Thus, the WD 22 may further comprise software 90, which is stored in, for example, memory 88 at the WD 22, or stored in external memory (e.g., database, storage array, network storage device, etc.) accessible by the WD 22. The software 90 may be executable by the processing circuitry 84. The software 90 may include a client application 92. The client application 92 may be operable to provide a service to a human or non-human user via the WD 22, with the support of the host computer 24. In the host computer 24, an executing host application 50 may communicate with the executing client application 92 via the OTT connection 52 terminating at the WD 22 and the host computer 24. In providing the service to the user, the client application 92 may receive request data from the host application 50 and provide user data in response to the request data. The OTT connection 52 may transfer both the request data and the user data. The client application 92 may interact with the user to generate the user data that it provides.

The processing circuitry 84 may be configured to control any of the methods and/or processes described herein and/or to cause such methods, and/or processes to be performed, e.g., by WD 22. The processor 86 corresponds to one or more processors 86 for performing WD 22 functions described herein. The WD 22 includes memory 88 that is configured to store data, programmatic software code and/or other information described herein. In some embodiments, the software 90 and/or the client application 92 may include instructions that, when executed by the processor 86 and/or processing circuitry 84, causes the processor 86 and/or processing circuitry 84 to perform the processes described herein with respect to WD 22.

In some embodiments, the inner workings of the network node 16, WD 22, and host computer 24 may be as shown in FIG. 2 and independently, the surrounding network topology may be that of FIG. 1.

In FIG. 2, the OTT connection 52 has been drawn abstractly to illustrate the communication between the host computer 24 and the wireless device 22 via the network node 16, without explicit reference to any intermediary devices and the precise routing of messages via these devices. Network infrastructure may determine the routing, which it may be configured to hide from the WD 22 or from the service provider operating the host computer 24, or both. While the OTT connection 52 is active, the network infrastructure may further take decisions by which it dynamically changes the routing (e.g., on the basis of load balancing consideration or reconfiguration of the network).

The wireless connection 64 between the WD 22 and the network node 16 is in accordance with the teachings of the embodiments described throughout this disclosure. One or more of the various embodiments improve the performance of OTT services provided to the WD 22 using the OTT connection 52, in which the wireless connection 64 may form the last segment. More precisely, the teachings of some of these embodiments may improve the data rate, latency, and/or power consumption and thereby provide benefits such as reduced user waiting time, relaxed restriction on file size, better responsiveness, extended battery lifetime, etc.

In some embodiments, a measurement procedure may be provided for the purpose of monitoring data rate, latency and other factors on which the one or more embodiments improve. There may further be an optional network functionality for reconfiguring the OTT connection 52 between the host computer 24 and WD 22, in response to variations in the measurement results. The measurement procedure and/or the network functionality for reconfiguring the OTT connection 52 may be implemented in the software 48 of the host computer 24 or in the software 90 of the WD 22, or both. In embodiments, sensors (not shown) may be deployed in or in association with communication devices through which the OTT connection 52 passes; the sensors may participate in the measurement procedure by supplying values of the monitored quantities exemplified above, or supplying values of other physical quantities from which software 48, 90 may compute or estimate the monitored quantities. The reconfiguring of the OTT connection 52 may include message format, retransmission settings, preferred routing etc.; the reconfiguring need not affect the network node 16, and it may be unknown or imperceptible to the network node 16. Some such procedures and functionalities may be known and practiced in the art. In certain embodiments, measurements may involve proprietary WD signaling facilitating the host computer's 24 measurements of throughput, propagation times, latency and the like. In some embodiments, the measurements may be implemented in that the software 48, 90 causes messages to be transmitted, in particular empty or ‘dummy’ messages, using the OTT connection 52 while it monitors propagation times, errors, etc.

Thus, in some embodiments, the host computer 24 includes processing circuitry 42 configured to provide user data and a communication interface 40 that is configured to forward the user data to a cellular network for transmission to the WD 22. In some embodiments, the cellular network also includes the network node 16 with a radio interface 62. In some embodiments, the network node 16 is configured to, and/or the network node's 16 processing circuitry 68 is configured to perform the functions and/or methods described herein for preparing/initiating/maintaining/supporting/ending a transmission to the WD 22, and/or preparing/terminating/maintaining/supporting/ending in receipt of a transmission from the WD 22.

In some embodiments, the host computer 24 includes processing circuitry 42 and a communication interface 40 that is configured to a communication interface 40 configured to receive user data originating from a transmission from a WD 22 to a network node 16. In some embodiments, the WD 22 is configured to, and/or comprises a radio interface 82 and/or processing circuitry 84 configured to perform the functions and/or methods described herein for preparing/initiating/maintaining/supporting/ending a transmission to the network node 16, and/or preparing/terminating/maintaining/supporting/ending in receipt of a transmission from the network node 16.

Although FIGS. 1 and 2 show “unit” such as BFP unit 32 as being within a respective processor, it is contemplated that these units may be implemented such that a portion of the unit is stored in a corresponding memory within the processing circuitry. In other words, the units may be implemented in hardware or in a combination of hardware and software within the processing circuitry.

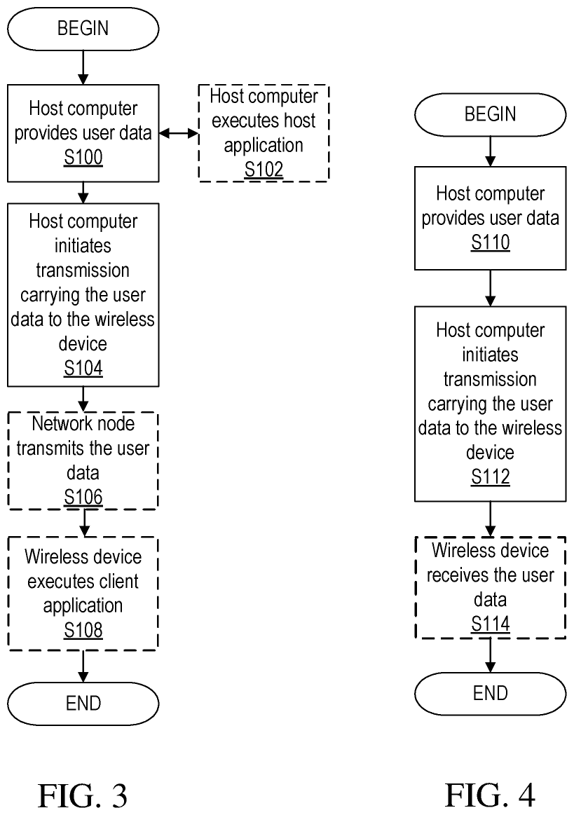

FIG. 3 is a flowchart illustrating an example method implemented in a communication system, such as, for example, the communication system of FIGS. 1 and 2, in accordance with one embodiment. The communication system may include a host computer 24, a network node 16 and a WD 22, which may be those described with reference to FIG. 2. In a first step of the method, the host computer 24 provides user data (Block S100). In an optional substep of the first step, the host computer 24 provides the user data by executing a host application, such as, for example, the host application 50 (Block S102). In a second step, the host computer 24 initiates a transmission carrying the user data to the WD 22 (Block S104). In an optional third step, the network node 16 transmits to the WD 22 the user data which was carried in the transmission that the host computer 24 initiated, in accordance with the teachings of the embodiments described throughout this disclosure (Block S106). In an optional fourth step, the WD 22 executes a client application, such as, for example, the client application 92, associated with the host application 50 executed by the host computer 24 (Block S108).

FIG. 4 is a flowchart illustrating an example method implemented in a communication system, such as, for example, the communication system of FIG. 1, in accordance with one embodiment. The communication system may include a host computer 24, a network node 16 and a WD 22, which may be those described with reference to FIGS. 1 and 2. In a first step of the method, the host computer 24 provides user data (Block S110). In an optional substep (not shown) the host computer 24 provides the user data by executing a host application, such as, for example, the host application 50. In a second step, the host computer 24 initiates a transmission carrying the user data to the WD 22 (Block S112). The transmission may pass via the network node 16, in accordance with the teachings of the embodiments described throughout this disclosure. In an optional third step, the WD 22 receives the user data carried in the transmission (Block S114).

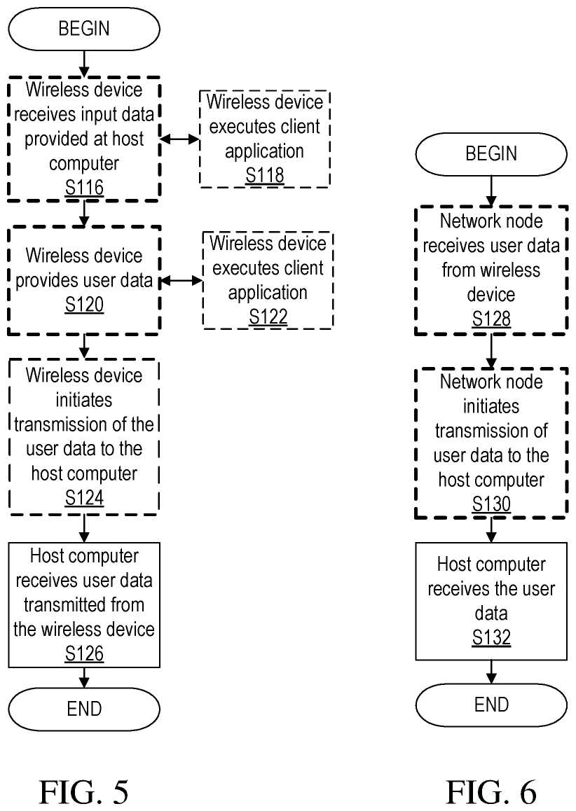

FIG. 5 is a flowchart illustrating an example method implemented in a communication system, such as, for example, the communication system of FIG. 1, in accordance with one embodiment. The communication system may include a host computer 24, a network node 16 and a WD 22, which may be those described with reference to FIGS. 1 and 2. In an optional first step of the method, the WD 22 receives input data provided by the host computer 24 (Block S116). In an optional substep of the first step, the WD 22 executes the client application 92, which provides the user data in reaction to the received input data provided by the host computer 24 (Block S118). Additionally or alternatively, in an optional second step, the WD 22 provides user data (Block S120). In an optional substep of the second step, the WD provides the user data by executing a client application, such as, for example, client application 92 (Block S122). In providing the user data, the executed client application 92 may further consider user input received from the user. Regardless of the specific manner in which the user data was provided, the WD 22 may initiate, in an optional third substep, transmission of the user data to the host computer 24 (Block S124). In a fourth step of the method, the host computer 24 receives the user data transmitted from the WD 22, in accordance with the teachings of the embodiments described throughout this disclosure (Block S126).

FIG. 6 is a flowchart illustrating an example method implemented in a communication system, such as, for example, the communication system of FIG. 1, in accordance with one embodiment. The communication system may include a host computer 24, a network node 16 and a WD 22, which may be those described with reference to FIGS. 1 and 2. In an optional first step of the method, in accordance with the teachings of the embodiments described throughout this disclosure, the network node 16 receives user data from the WD 22 (Block S128). In an optional second step, the network node 16 initiates transmission of the received user data to the host computer 24 (Block S130). In a third step, the host computer 24 receives the user data carried in the transmission initiated by the network node 16 (Block S132).

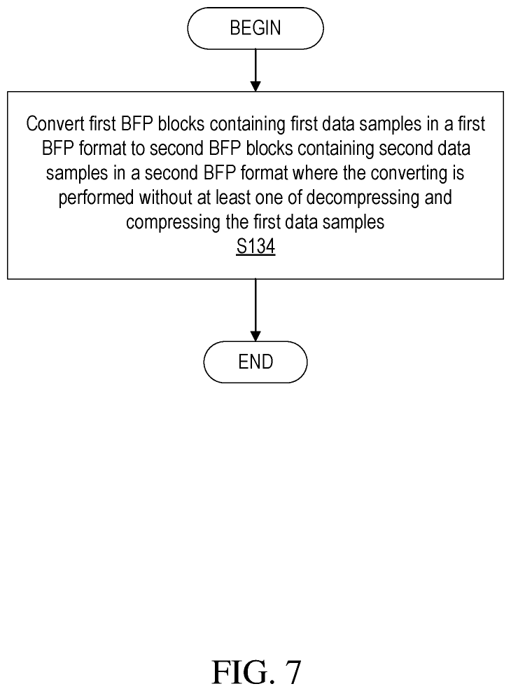

FIG. 7 is a flowchart of an example process in a computing device, such as a network node 16, according to one or more embodiments of the present disclosure. One or more blocks described herein may be performed by one or more elements of network node 16 such as by one or more of processing circuitry 68 (including the BFP unit 32), processor 70, radio interface 62 and/or communication interface 60. Network node 16 such as via processing circuitry 68 and/or processor 70 and/or radio interface 62 and/or communication interface 60 is configured to convert (Block S134) first BFP blocks containing first data samples in a first BFP format to second BFP blocks containing second data samples in a second BFP format where the converting is performed without at least one of decompressing and compressing the first data samples, as described herein.

According to one or more embodiments, the first data samples are smaller than the second data samples. According to one or more embodiments, the first data samples are larger than the first data samples. According to one or more embodiments, the converting includes: breaking the first BFP blocks into subsets based on a number of the first BFP blocks that share an exponent, and
for each subset:
   determine a smallest exponent in the subset
   for each input bundle that shares the exponent:
      calculate a left shift due to a change in sample length;
      calculate a right shift due to exponent adjustment;
      for each negative sample, fill left of sample with 1s;
      for all data samples, shift left data sample by the calculated left shift amount;
      for all data samples, shift right data sample by the calculated right shift amount;
      select only bits required for a BFP sample; and
      new exponent for resulting output block is a smallest exponent from the first BFP blocks.

According to one or more embodiments, the converting includes breaking the first BFP blocks into subsets based on a number of the first BFP blocks that share an exponent, and
for each subset:
   determine a smallest exponent in the subset
   for each input bundle that shares the exponent:
      calculate a first right shift due to a change in sample length;
      calculate a second right shift due to exponent adjustment;
      for each negative sample, fill left of sample with 1s;
      for all data samples, shift right bits of the data sample by the calculated first right shift and calculated second right shift;
      select only bits required for a BFP sample; and
      new exponent for resulting output block is a smallest exponent from the first BFP blocks.

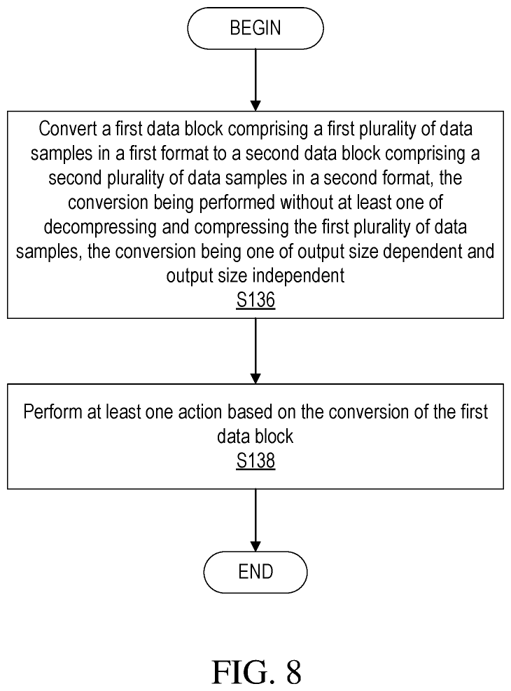

FIG. 8 is another flowchart of an example process in a computing device, such as a network node 16, according to one or more embodiments of the present disclosure. One or more blocks described herein may be performed by one or more elements of network node 16 such as by one or more of processing circuitry 68 (including the BFP unit 32), processor 70, radio interface 62 and/or communication interface 60. Network node 16 such as via processing circuitry 68 and/or processor 70 and/or radio interface 62 and/or communication interface 60 is configured to convert (Block S138) a first data block comprising a first plurality of data samples in a first format to a second data block comprising a second plurality of data samples in a second format. The conversion is performed without at least one of decompressing and compressing the first plurality of data sample. Further, the conversion is one of output size dependent and output size independent. In addition, network node 16 such as via processing circuitry 68 and/or processor 70 and/or radio interface 62 and/or communication interface 60 is configured to perform (Block S140) at least one action based on the conversion of the first data block.

In some embodiments, the first data block comprises a first least significant bit (LSB), the second data block comprises a second LSB, and the conversion of the first data block includes determining a first bit string based on whether the conversion is one of output size dependent and output size independent. The first bit string comprises a first bit string LSB. Further, the first bit string is appended to the right of second LSB of the second data block, where the first bit string LSB of the first bit string becomes the only LSB of the appended second data block.

In some other embodiments, the first data block comprises at least a first exponent, and the first bit string comprises at least a second exponent.

In an embodiment, the method further includes, when the conversion is output size dependent, determining the at least second exponent to be the same as the at least first exponent if a first size of the first plurality of data samples is less than or equal to a second size of the second plurality of data samples; and based at least in part on a minimum exponent value of the at least first exponent if the first size of the first plurality of data samples is greater than the second size of the second plurality of data samples.

In another embodiment, the method further includes, when the conversion is output size independent, determining the at least second exponent to be the same as the at least first exponent if the first size of the first plurality of data samples is less than or equal to the second size of the second plurality of data samples; and based at least in part on a maximum exponent value of the at least first exponent if the first size of the first plurality of data samples is greater than the second size of the second plurality of data samples.

In some embodiments, the conversion of the first data block further includes appending a plurality of padding bits to the first data block; determining a plurality of right shift bits, where the plurality of right shift bits is based on the minimum exponent value when the conversion is output size dependent. The plurality of right shift bits is based on the maximum exponent value when the conversion is output size independent. In addition, the first plurality of data samples is shifted to the right by a number of bits equal to the plurality of right shift bits.

In some other embodiments, the conversion of the first data block further includes setting at least one bit of the plurality of right shift bits to zero when a first value associated with the first plurality of data samples is positive; and setting at least one other bit of the plurality of right shift bits to one when a second value associated with the first plurality of data samples is negative.

In an embodiment, the second data block further includes a second most significant bit (MSB), and the conversion of the first data block includes, when a third value associated with the first plurality of data samples is a negative value, inserting a second bit string to the right of the second MSB. Each bit of the second bit string is equal to one.

In another embodiment, the first data block is a first block float point (BFP) block, and the second data block is a second BFP block.

In some embodiments, the performing of the at least one action includes at least one of receiving the first data block; transmitting the second data block; extracting data from at least from the second plurality of data samples; and performing at least one network function based on the extracted data.

Having described the general process flow of arrangements of the disclosure and having provided examples of hardware and software arrangements for implementing the processes and functions of the disclosure, the sections below provide details and examples of arrangements for block floating point (BFP) conversion without decompressing and compressing again the data.

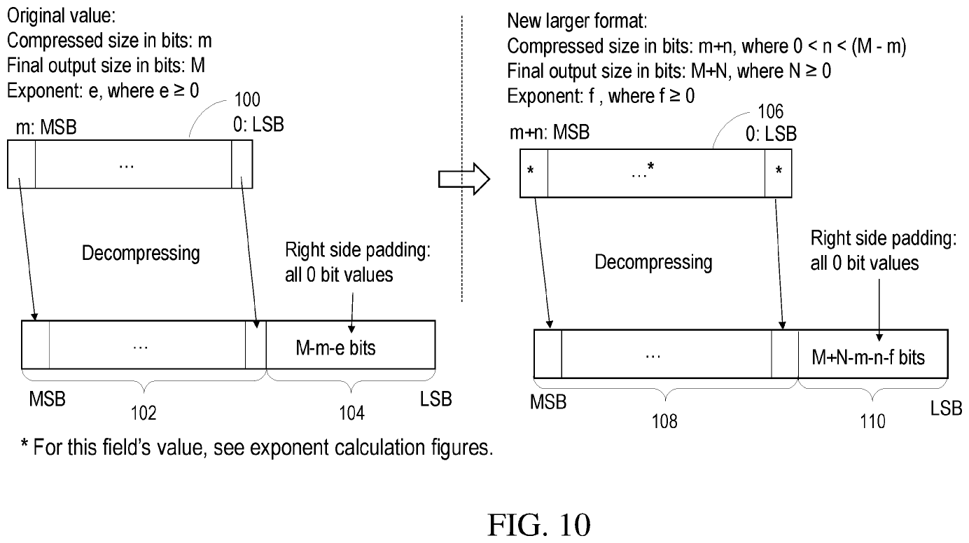

In some embodiments, one or both of the first and second data blocks may refer to (and/or comprise) any one of blocks 100, 102, 106, 108, 120, 126, 132 shown in on or another of FIGS. 10-17, described herein. Further, one or both of the first and second data blocks may be and/or comprise other components such as bit strings 104, 110, 112, 114, 122, 124, 128, 130, 134, 136 of FIGS. 10-17. In some other embodiments, a bit string may refer to a field of a block that comprises the bit string.

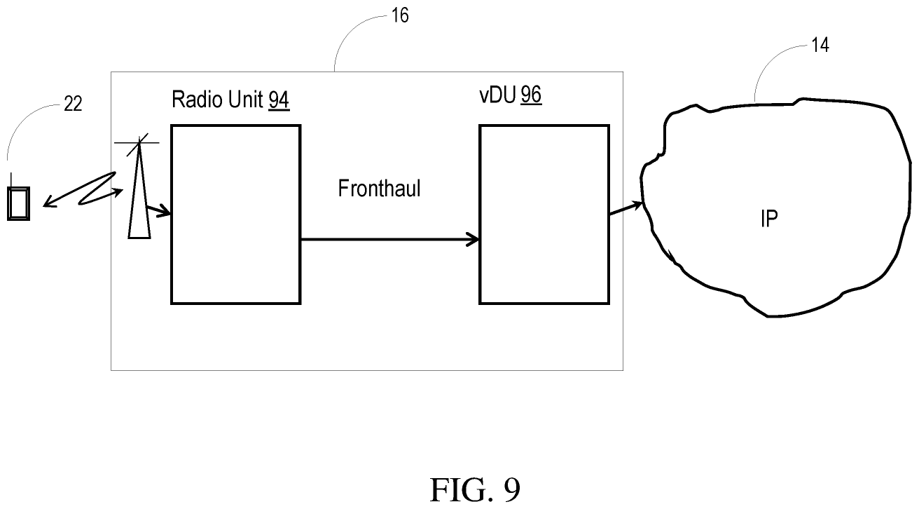

FIG. 9 is another schematic diagram of an example network architecture using uplink IQ antenna data processing and transmission according to some embodiments of the present disclosure. Network node 16 may comprise a radio unit 94 and/or vDU 96, any of which may be comprised in (and/or in communication with) BFP unit 32 and/or communication interface 60 and/o radio interface 62 and/or processing circuitry 68.

shown in FIG. 2. Network node 16 may be configured to communicate with WD 22 and/or core network 14 (e.g., internet, using internet protocol (IP), etc.). Although core network 14 is shown, network node 16 may be configured to communicate with any other type of network. Further, network node 16 may be configured to receive and transmit one or more blocks (such as data blocks), which may have been compressed and may include one or more samples of data. The samples and/or blocks may be converted to a format (e.g., different from the format present when received by network node 16), with or without the use of compression and/or decompression.

In one nonlimiting example, radio unit 94 of network node 16 receives, every 0.5 milliseconds, 64 streams of IQ data from the antennas of network node 16, which may include 419,32816 samples, 16 bit long each (e.g., 100 MHz bandwidth). The radio unit 94 may be configured to group the samples into blocks of 4 samples and compress from 16 bit to 7 bits as follows:

FBP7={sample1, sample2, sample3, sample4, exponent}, e.g., where samples are 7 bit long and exponent is 4 bits long.

For ORAN, the radio unit 94 may be configured to change the format to BFP8 or BFP9, with 24 8-bit or 9-bit samples per block. The data may be transmitted to vDU 96. The vDU may be configured to decompresses the data into 16 bit samples and consume it (e.g., control data) and/or forward it to the internet (e.g., user data).

FIG. 10 is an example conversion of positive values (e.g., output size dependent), according to some embodiments of the present disclosure. A first block 100 (e.g., data block) comprising one or more data samples in a first format may be converted (e.g., by network node 16 or any of its components) to a second block 106 (e.g., data block) comprising one or more data samples in a second format. The first block 100 may comprise a plurality of compressed bits (e.g., of a size m), the first block may be decompressed (and/or comprise) block 102 and bit string 104, which may comprise or have size given by M-m-e bits. M may refer to a final output size in bits, and “e” may refer to an exponent.

Converted second block 106 may comprise more bits than the first block 100, where second block 106 may comprise m+n bits, where 0<n< (M-m). The final outputs size in bits may be M+N, where N≥0. Second block 106 may comprise and/or be decompressed to produce block 108 and/or bit string 110. Bit string 110 may comprise M+N-m-n-f bits, where f is an exponent. In some embodiments, bit strings 104, 110 may be part of a right side padding process which includes all 0 bit values.

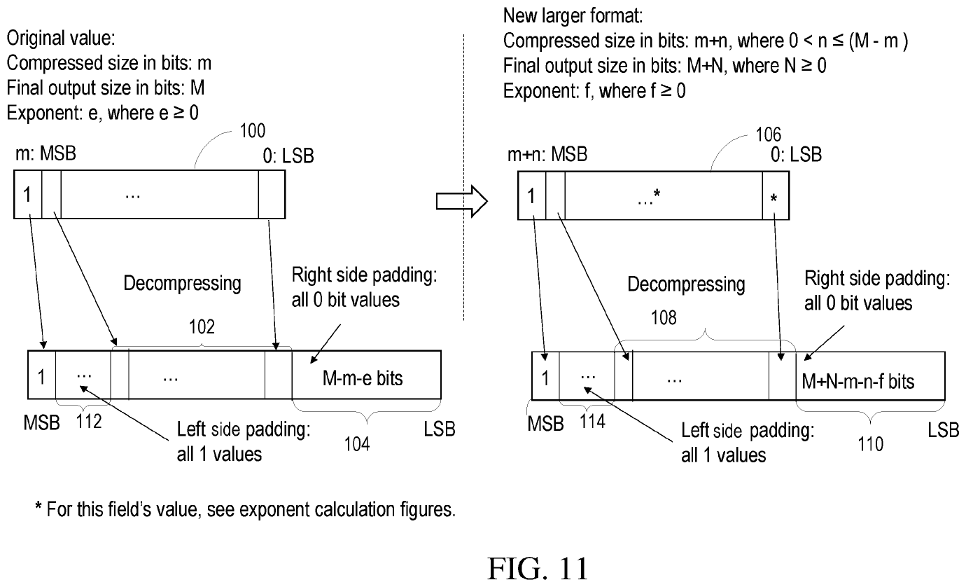

FIG. 11 is an example conversion of negative values in two's complement (e.g., an output size dependent) according to some embodiments of the present disclosure. More specifically, bit string 112 may be inserted to the left of block 102, i.e., block 102 may to the right of bit string 112, where bit string 112 may be part of a left side padding. Similarly, bit string 114 may be inserted to the left of block 108, i.e., bit string 114 may to the right of bit string 114, where bit string 114 may be part of a left side padding. In some embodiments, bit strings 112, 114 may be part of a left side padding process which includes all 1 bit values.

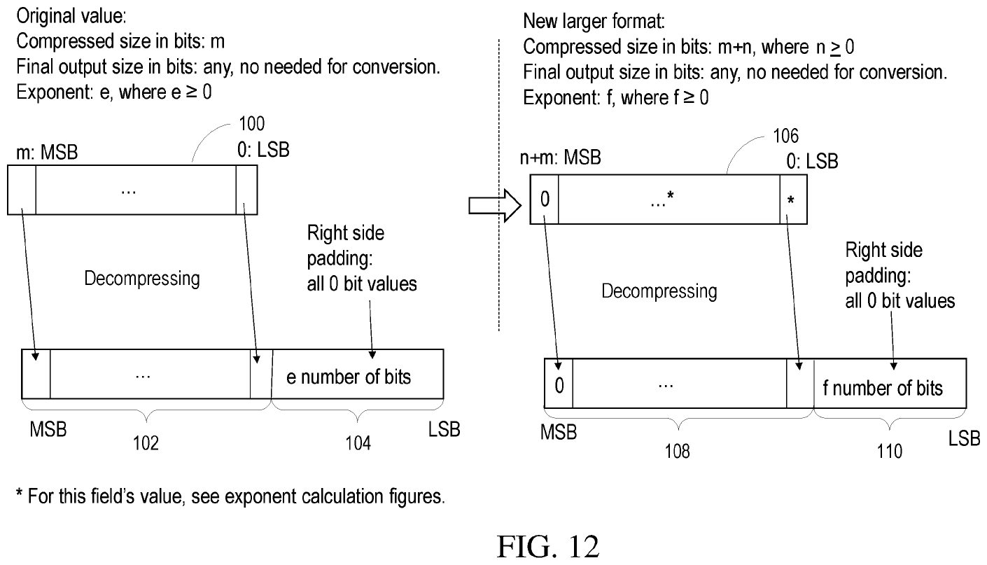

FIG. 12 is an example conversion of positive values (e.g., output size independent) according to some embodiments of the present disclosure. In a nonlimiting example, bit string 104 may comprise “e” number of bits, where “e” is an exponent greater or equal to zero. Similarly, bit string 110 may comprise “f” number of bits, where “f” is an exponent greater or equal to zero. Bit strings 102, 110 may be appended to blocks 102, 108, respectively, as part of a right side padding process, which may include all 0 bit values. The compressed size in bits (e.g., of the second block 106) may be m+n, where n≥0. In some embodiments, the final output size in bits may not be used for processing any one of the blocks and/or bit strings.

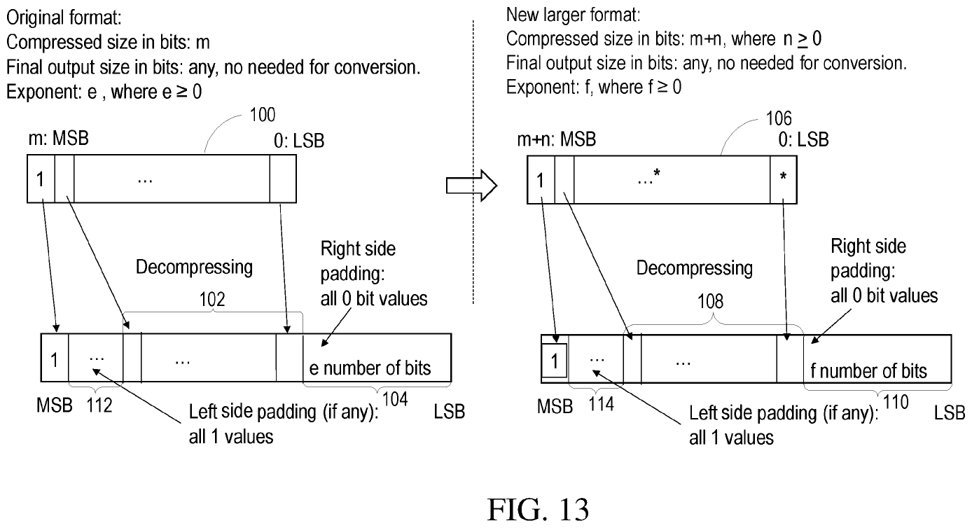

FIG. 13 is an example conversion of negative values in two's complement (output size independent) according to some embodiments of the present disclosure. More specifically, bit string 112 may be inserted to the left of block 102, where bit string 112 may be part of a left side padding. Similarly, bit string 114 may be inserted to the left of block 108, where bit string 114 may be part of a left side padding. In some embodiments, bit strings 112, 114 may be part of a left side padding process which includes all 1 bit values. Further, bit string 104 (comprising “e” number of bits) may be right padded (i.e., appended to) block 102, and bit string 110 (comprising “f” number of bits) may be right padded (i.e., appended to) block 108. In some embodiments, the compressed size in bits associated with block 106 may be m+n, where n≥0. The value of block 106 as denoted by the “*” may be determined based on the exponent calculation figures set forth herein. With respect to the final output size in bits associated with blocks 100, 108, in some embodiments, the final output size may not be needed/used for conversion.

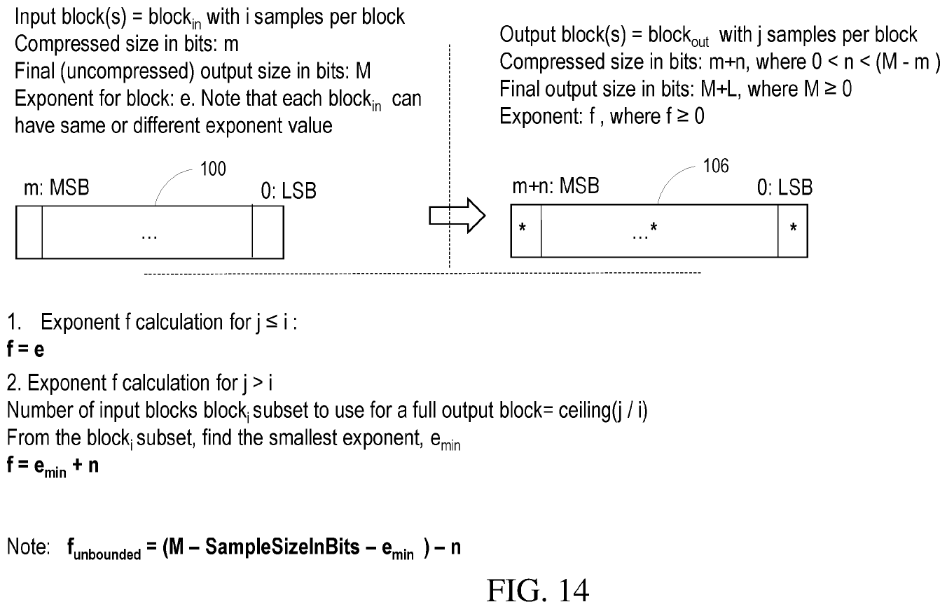

FIG. 14 is an example exponent calculation (output size dependent) according to some embodiments of the present disclosure. The exponent may be comprised in any one of blocks shown in FIGS. 10-13, such as blocks 100, 106. More specifically, exponent “f” may be determined for j≤ i, where f=e, and for j>i, a number of input blocks block; subset may be used for a full output block, where the full output block=ceiling (j/i). From the blockᵢ subset, the smallest exponent, eₘᵢₙ, may be determined from f=eₘᵢₙ+n. In some embodiments, f_{unbounded} may also be determined where f_{unbounded}=(M-SampleSizeInBits-eₘᵢₙ)-n. First block 100 may be and/or comprise input blockᵢₙ, and second block 106 may be and/or comprise output blockₒᵤₜ.

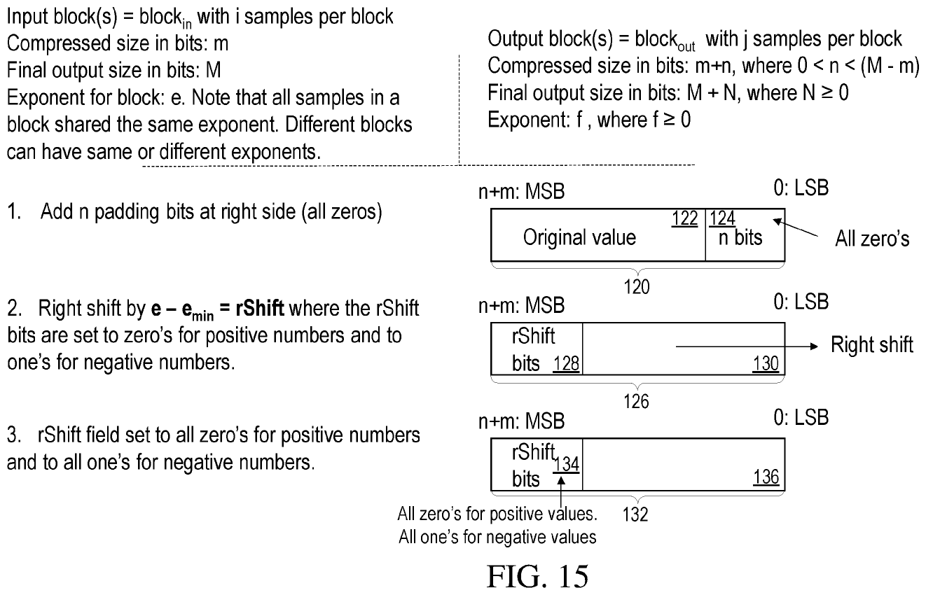

FIG. 15 is an example value calculation (output size dependent) according to some embodiments of the present disclosure. More specifically, block 120 may comprise bit strings 122 (e.g., original value) and bit string 124, where bit string 124 are part of a padding process (i.e., added/appended to the right of bit string 122). A right shift may be performed, where one or more bits such as bit string 130 of block 126 is shifted to the right. Further, the right shift (rShift=e-eₘᵢₙ) bits of bit string 134 of block 132 are set to zero for positive numbers and to one for negative numbers, and bit string 136 may be similar or equal to bit string 130. In some embodiments, block 126 is block 120 after a right shift, and block 132 is block 126 after adding zeros or ones to bit string 128 (rShift bits).

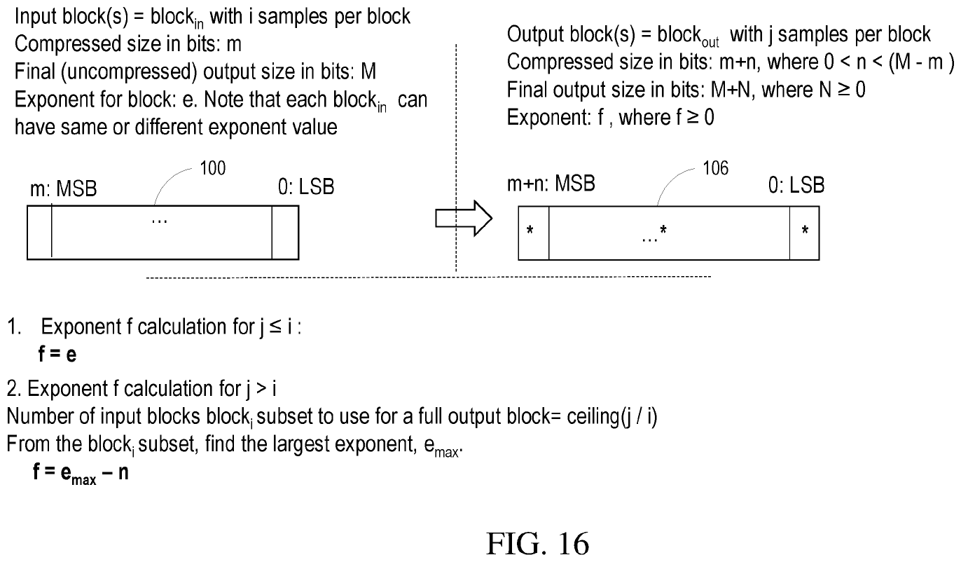

FIG. 16 is an example exponent calculation (output size independent) according to some embodiments of the present disclosure. The exponent may be comprised in any one of blocks shown in FIGS. 10-13, such as blocks 100, 106. More specifically, exponent “f” may be determined for j≤ i, where f=e, and for j>i, a number of input blocks block; subset may be used for a full output block, where the full output block=ceiling (j/i). From the block; subset, the largest exponent, eₘₐₓ, may be determined from f=eₘₐₓ-n. First block 100 may be and/or comprise input blockᵢₙ, and second block 106 may be and/or comprise output blockₒᵤₜ.

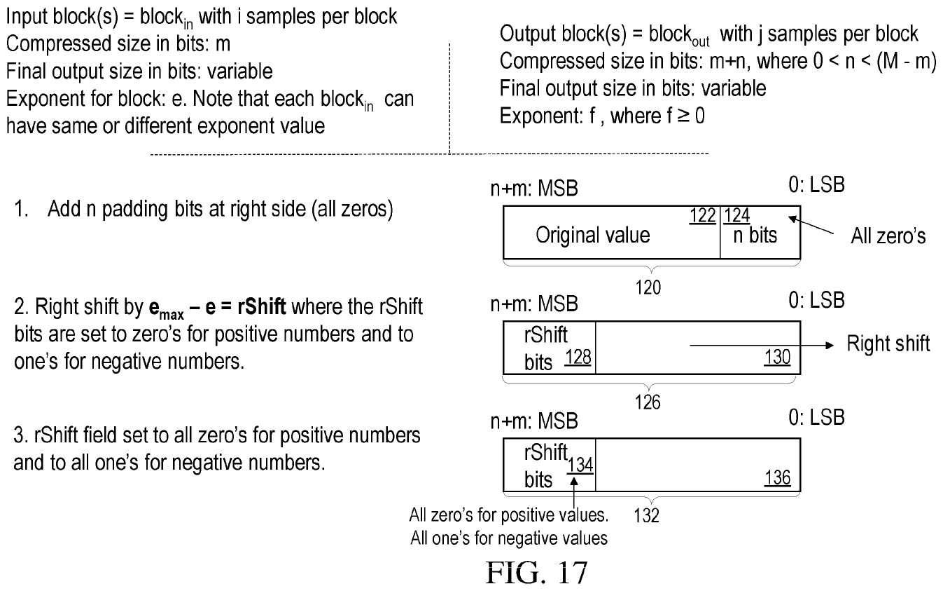

FIG. 17 is an example value calculation (output size independent) according to some embodiments of the present disclosure. More specifically, block 120 may comprise bit strings 122 (e.g., original value) and bit string 124, where bit string 124 are part of a padding process (i.e., added/appended to the right of bit string 122). A right shift may be performed, where one or more bits such as bit string 130 of block 126 is shifted to the right. Further, the right shift (rShift=e-eₘₐₓ) bits of bit string 134 of block 132 are set to zero for positive numbers and to one for negative numbers, and bit string 136 may be similar or equal to bit string 130. In some embodiments, block 126 is block 120 after a right shift, and block 132 is block 126 after adding zeros or ones to bit string 128 (rShift bits).

Some embodiments provide block floating point (BFP) conversion without decompressing and again compressing the data. One or more functions/steps described below may be performed by one or more of processing circuitry 68, processor 70, BFP unit 32, communication interface 60, etc., in a network node 16 or in a computing device with similar constituent hardware elements.

Given a set BFP blocks (e.g., at least one first block 100) containing data samples in a BFP format (e.g., BFP7 or 4×7+4, which are examples of BFP formats), covert the data directly to another BFP format (e.g., BFP8 or BFP9, which are examples of BFP formats) without decompressing and/or compressing again the data. Two example algorithms are described below.

Algorithm 1 performs conversion of BFP blocks (e.g., blocks 100) with smaller data sample to BFP blocks (e.g., blocks 106) with larger samples, e.g., 4×7+4 to BFP8, or BFP8 to BFP9. More specifically, algorithm 1 may include one or more of the following:

### Definition

inputSampleSize: size in bits of input samples. For example, for BFP7 the sample size is 7.

outputSampleSize: size in bits of output samples. For example, for BFP8, the sample size is 8.
1. Break the input BFP blocks into subsets based on the number of input blocks to share the same new exponent.
2. For input block subset from step 1 above, perform the following:
   a. Find the smallest exponent, expₘᵢₙ in the input block subset: see getMinExp ( ) below
   b. For each input bundle to share an exponent, perform the following:
      i. Calculate the left shift required due to the change in sample length.
         leftShift=outputSampleSize-inputSampleSize
      ii. Calculate right shift required due to exponent adjustment:
         rightShift=inputBundle.exponent-minExp
         rightShift=min (rightShift, outputSampleSize)
      iii. For each negative sample (most significant bit=1), perform the following:
         Fill left of sample with 1's:
         Example in C/C++: for 8 bit long data sample located at the 8 least significant bits:
         if (sample4 & 0x80)//if sign bit is 1=>negative value sample4|=0xFFFFFF80;//fill left side with 1's.
      iv. For all data samples, shift left data sample by “leftShift” calculated above. C/C++ example:
         sample4=sample4<<leftShift;
         Note: “leftShift” is calculated above
      v. For all data samples, shift right data sample by “rightShift”.
         C/C++ example:
         sample4=sample4>>rightShift;
         Note: “rightShift” is calculated above.
      vi. Choose only the bits required for the BFP sample.
         C/C++ example:
         sample4=sample4 & (0xFFFF>> (16-outputSampleSize);
      vii. New exponent to use for new resulting output block is minExp (calculated above)

```
    //find the minimum exponent of all the input BFP blocks to share
    an exponent
// returns the smallest exponent used by the input blocks
Unsigned int getMinExp(inputBlocks, numberOfBlocks)
{
  1. Loop through all blocks
      a. minExp = the smallest exponent from all the input blocks
  2. Return minExp.
      }
```

In one or more embodiments, examples from an ORAN implementation perspective may correspond converting compressed data in 4×7+4 (e.g., one format) to BFP8.

Algorithm 2 performs conversion of BFP blocks of larger sample size to smaller sample size (e.g., BFP9 to BFP8). More specifically, algorithm 1 may include one or more of the following:

### Definition

inputSampleSize: size in bits of input samples. For example, for BFP9 the sample size is 9.

outputSampleSize: size in bits of output samples. For example, for BFP8, the sample size is 8.
1. Break the input BFP blocks into subsets based on the number of input blocks to share the same new exponent.
2. For input block subset from step 1 (Algorithm 2) above, perform the following:
   a. Find the smallest exponent, expₘᵢₙ in the input block subset: see getMinExp ( ) below
   b. For each input bundle to share an exponent, perform the following:
      i. Calculate the right shift required due to the change in sample length.
         shiftRight_1=inputSampleSize-outputSampleSize
      ii. Calculate right shift required due to exponent adjustment:
         shiftRight_2=inputBundle.exponent-minExp
         shiftRight_2=min (shift, outputSampleSize)
      iii. For each negative sample (most significant bit=1), perform the following:
         Fill left of sample with 1's:
         Example in C/C++: for 8 bit long data sample located at the 8 least significant bits:
         if (sample4 & 0x80)//if sign bit is 1=>negative value sample4|=0xFFFFFF80;//fill left side with 1's.
      iv. For all data samples, right shift bits of data samples by “shiftRight_1+shiftRight_2”. C/C++ example:
         sample4=((sample4>> (shiftRight_1+shiftRight_2));
         Note: “shiftRight_1 and shiftRight_2” are calculated above.
      viii. Choose only the bits required for the BFP sample.
         C/C++ example:
         sample4=sample4 & (0xFFFF>> (16-outputSampleSize);
      v. New exponent to use for new resulting output block is minExp (calculated above).

The following is a nonlimiting list of example embodiments:

Embodiment A1. A computing device (e.g., network node 16) configured to, and/or comprising processing circuitry 68 configured to:
convert first block floating point, BFP, blocks 100 containing first data samples in a first BFP format to second BFP blocks 106 containing second data samples in a second BFP format, the converting being performed without at least one of decompressing and compressing the first data samples.

Embodiment A2. The computing device (e.g., network node 16) of Embodiment A1, wherein the first data samples are smaller than the second data samples.

Embodiment A3. The computing device (e.g., network node 16) of Embodiment A1, wherein the first data samples are larger than the first data samples.

Embodiment A4. The computing device (e.g., network node 16) of Embodiment A1, wherein the converting includes:
breaking the first BFP blocks 100 into subsets based on a number of the first BFP blocks 100 that share an exponent; and
for each subset:
   determine a smallest exponent in the subset
   for each input bundle that shares the exponent:
      calculate a left shift due to a change in sample length;
      calculate a right shift due to exponent adjustment;
      for each negative sample, fill left of sample with 1s;
      for all data samples, shift left data sample by the calculated left shift amount;
      for all data samples, shift right data sample by the calculated right shift amount;
      select only bits required for a BFP sample; and
      new exponent for resulting output block is a smallest exponent from the first BFP blocks 100.

Embodiment A5. The computing device (e.g., network node 16) of Embodiment A1, wherein the converting includes:
breaking the first BFP blocks into subsets based on a number of the first BFP blocks that share an exponent; and
for each subset:
   determine a smallest exponent in the subset
   for each input bundle that shares the exponent:
      calculate a first right shift due to a change in sample length;
      calculate a second right shift due to exponent adjustment;
      for each negative sample, fill left of sample with 1s;
      for all data samples, shift right bits of the data sample by the calculated first right shift and calculated second right shift;
      select only bits required for a BFP sample; and
      new exponent for resulting output block is a smallest exponent from the first BFP blocks 100.

Embodiment B1. A method implemented in a computing device (e.g., network node 16), the method comprising converting first block floating point, BFP, blocks 100 containing first data samples in a first BFP format to second BFP blocks 106 containing second data samples in a second BFP format, the converting being performed without at least one of decompressing and compressing the first data samples.

Embodiment B2. The method of Embodiment B1, wherein the first data samples are smaller than the second data samples.

Embodiment B3. The method of Embodiment B1, wherein the first data samples are larger than the first data samples.

Embodiment B4. The method of Embodiment B1, wherein the converting includes:
breaking the first BFP blocks 100 into subsets based on a number of the first BFP blocks 100 that share an exponent; and
for each subset:
   determine a smallest exponent in the subset
   for each input bundle that shares the exponent:
      calculate a left shift due to a change in sample length;
      calculate a right shift due to exponent adjustment;
      for each negative sample, fill left of sample with 1s;
      for all data samples, shift left data sample by the calculated left shift amount;
      for all data samples, shift right data sample by the calculated right shift amount;
      select only bits required for a BFP sample; and
      new exponent for resulting output block is a smallest exponent from the first BFP blocks 100.

Embodiment B5. The method of Embodiment B1, wherein the converting includes:
breaking the first BFP blocks 100 into subsets based on a number of the first BFP blocks 100 that share an exponent; and
for each subset:
   determine a smallest exponent in the subset
   for each input bundle that shares the exponent:
      calculate a first right shift due to a change in sample length;
      calculate a second right shift due to exponent adjustment;
      for each negative sample, fill left of sample with 1s;
      for all data samples, shift right bits of the data sample by the calculated first right shift and calculated second right shift;
      select only bits required for a BFP sample; and
      new exponent for resulting output block is a smallest exponent from the first BFP blocks 100.

As will be appreciated by one of skill in the art, the concepts described herein may be embodied as a method, data processing system, computer program product and/or computer storage media storing an executable computer program. Accordingly, the concepts described herein may take the form of an entirely hardware embodiment, an entirely software embodiment or an embodiment combining software and hardware aspects all generally referred to herein as a “circuit” or “module.” Any process, step, action and/or functionality described herein may be performed by, and/or associated to, a corresponding module, which may be implemented in software and/or firmware and/or hardware. Furthermore, the disclosure may take the form of a computer program product on a tangible computer usable storage medium having computer program code embodied in the medium that can be executed by a computer. Any suitable tangible computer readable medium may be utilized including hard disks, CD-ROMs, electronic storage devices, optical storage devices, or magnetic storage devices.

Some embodiments are described herein with reference to flowchart illustrations and/or block diagrams of methods, systems and computer program products. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer (to thereby create a special purpose computer), special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable memory or storage medium that can direct a computer or other programmable data processing apparatus to function in a particular manner, such that the instructions stored in the computer readable memory produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions/acts specified in the flowchart and/or block diagram block or blocks.

It is to be understood that the functions/acts noted in the blocks may occur out of the order noted in the operational illustrations. For example, two blocks shown in succession may in fact be executed substantially concurrently or the blocks may sometimes be executed in the reverse order, depending upon the functionality/acts involved. Although some of the diagrams include arrows on communication paths to show a primary direction of communication, it is to be understood that communication may occur in the opposite direction to the depicted arrows.

Computer program code for carrying out operations of the concepts described herein may be written in an object oriented programming language such as Python, Java® or C++. However, the computer program code for carrying out operations of the disclosure may also be written in conventional procedural programming languages, such as the “C” programming language. The program code may execute entirely on the user's computer, partly on the user's computer, as a stand-alone software package, partly on the user's computer and partly on a remote computer or entirely on the remote computer. In the latter scenario, the remote computer may be connected to the user's computer through a local area network (LAN) or a wide area network (WAN), or the connection may be made to an external computer (for example, through the Internet using an Internet Service Provider).

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall be construed to constitute a complete written description of all combinations and subcombinations of the embodiments described herein, and of the manner and process of making and using them, and shall support claims to any such combination or subcombination.

It will be appreciated by persons skilled in the art that the embodiments described herein are not limited to what has been particularly shown and described herein above. In addition, unless mention was made above to the contrary, it should be noted that all of the accompanying drawings are not to scale. A variety of modifications and variations are possible in light of the above teachings without departing from the scope of the following claims.

1. A computing device comprising processing circuitry configured to:
convert a first data block comprising a first plurality of data samples in a first format to a second data block comprising a second plurality of data samples in a second format, the conversion being performed without at least one of decompressing and compressing the first plurality of data samples, the conversion being one of output size dependent and output size independent; and
perform at least one action based on the conversion of the first data block.

2. The computing device of claim 1, wherein the first data block comprises a first least significant bit, LSB, and the second data block comprises a second LSB, and the conversion of the first data block includes:
determining a first bit string based on whether the conversion is one of output size dependent and output size independent, the first bit string comprising a first bit string LSB; and
appending the first bit string to the right of the second LSB of the second data block, the first bit string LSB of the first bit string becoming the only LSB of the appended second data block.

3. The computing device of claim 2, wherein the first data block comprises at least a first exponent, and the first bit string comprises at least a second exponent.

4. The computing device of claim 3, wherein the processing circuitry is further configured to:
when the conversion is output size dependent, determine the at least second exponent to be:
the same as the at least first exponent if a first size of the first plurality of data samples is less than or equal to a second size of the second plurality of data samples; and
based at least in part on a minimum exponent value of the at least first exponent if the first size of the first plurality of data samples is greater than the second size of the second plurality of data samples.

5. The computing device of claim 4, wherein the processing circuitry is further configured to:
when the conversion is output size independent, determine the at least second exponent to be:
the same as the at least first exponent if the first size of the first plurality of data samples is less than or equal to the second size of the second plurality of data samples; and
based at least in part on a maximum exponent value of the at least first exponent if the first size of the first plurality of data samples is greater than the second size of the second plurality of data samples.

6. The computing device of claim 5, wherein the conversion of the first data block further includes:
appending a plurality of padding bits to the first data block;
determining a plurality of right shift bits, the plurality of right shift bits being based on the minimum exponent value when the conversion is output size dependent, the plurality of right shift bits being based on the maximum exponent value when the conversion is output size independent; and
shifting the first plurality of data samples to the right by a number of bits equal to the plurality of right shift bits.

7. The computing device of claim 6, wherein the conversion of the first data block further includes:
setting at least one bit of the plurality of right shift bits to zero when a first value associated with the first plurality of data samples is positive; and
setting at least one other bit of the plurality of right shift bits to one when a second value associated with the first plurality of data samples is negative.

8. The computing device of claim 1, wherein the second data block further includes a second most significant bit, MSB, and the conversion of the first data block includes:
when a third value associated with the first plurality of data samples is a negative value, inserting a second bit string to the right of the second MSB, each bit of the second bit string being equal to one.

9. The computing device of claim 1, wherein the first data block is a first block float point, BFP, block, and the second data block is a second BFP block.

10. The computing device of claim 1, wherein the performing of the at least one action includes at least one of:
receiving the first data block;
transmitting the second data block;
extract data from at least from the second plurality of data samples; and
perform at least one network function based on the extracted data.

11. A method in a computing device, the method comprising:
converting a first data block comprising a first plurality of data samples in a first format to a second data block comprising a second plurality of data samples in a second format, the conversion being performed without at least one of decompressing and compressing the first plurality of data samples, the conversion being one of output size dependent and output size independent; and
performing at least one action based on the conversion of the first data block.

12. The method of claim 11, wherein the first data block comprises a first least significant bit, LSB, and the second data block comprises a second LSB, and the conversion of the first data block includes:
determining a first bit string based on whether the conversion is one of output size dependent and output size independent, the first bit string comprising a first bit string LSB; and
appending the first bit string to the right of second LSB of the second data block, the first bit string LSB of the first bit string becoming the only LSB of the appended second data block.

13. The method of claim 12, wherein the first data block comprises at least a first exponent, and the first bit string comprises at least a second exponent.

14. The method of claim 13, wherein the method further includes:
when the conversion is output size dependent, determining the at least second exponent to be:
the same as the at least first exponent if a first size of the first plurality of data samples is less than or equal to a second size of the second plurality of data samples; and
based at least in part on a minimum exponent value of the at least first exponent if the first size of the first plurality of data samples is greater than the second size of the second plurality of data samples.

15. The method of claim 14, wherein the method further includes:
when the conversion is output size independent, determining the at least second exponent to be:
the same as the at least first exponent if the first size of the first plurality of data samples is less than or equal to the second size of the second plurality of data samples; and
based at least in part on a maximum exponent value of the at least first exponent if the first size of the first plurality of data samples is greater than the second size of the second plurality of data samples.

16. The method of claim 15, wherein the conversion of the first data block further includes:
appending a plurality of padding bits to the first data block;
determining a plurality of right shift bits, the plurality of right shift bits being based on the minimum exponent value when the conversion is output size dependent, the plurality of right shift bits being based on the maximum exponent value when the conversion is output size independent; and
shifting the first plurality of data samples to the right by a number of bits equal to the plurality of right shift bits.

17. The method of claim 16, wherein the conversion of the first data block further includes:
setting at least one bit of the plurality of right shift bits to zero when a first value associated with the first plurality of data samples is positive; and
setting at least one other bit of the plurality of right shift bits to one when a second value associated with the first plurality of data samples is negative.

18. The method of claim 11, wherein the second data block further includes a second most significant bit, MSB, and the conversion of the first data block includes:
when a third value associated with the first plurality of data samples is a negative value, inserting a second bit string to the right of the second MSB, each bit of the second bit string being equal to one.

19. The method of claim 11, wherein the first data block is a first block float point, BFP, block, and the second data block is a second BFP block.

20. The method of claim 11, wherein the performing of the at least one action includes at least one of:
receiving the first data block;
transmitting the second data block;
extracting data from at least from the second plurality of data samples; and
performing at least one network function based on the extracted data.
